(19) United States
(12) Patent Application Publication
(10) Pub. No.: US 2004/0187769 A1
(43) Pub. Date: Sep. 30, 2004

(54) Method of producing SOI wafer

(76) Inventor: Yoshirou Aoki, Tokyo (JP)

Correspondence Address: KANESAKA & TAKEUCHI, 1423 Powhatan Street, Alexandria, VA, 22314, US

(21) Appl. No.: 10/397,532

(22) Filed: Mar. 27, 2003

(51) Int. Cl. C30B 23/00; C30B 25/00; C30B 28/12; C30B 28/14

(52) U.S. Cl. 117/95

(57) ABSTRACT

A method of producing an SOI wafer comprises the steps of forming an ion-implanted layer by forming an oxide film on at least one silicon wafer between two silicon wafers and implanting hydrogen ions or rare gas ions into one silicon wafer, superposing the surface of the silicon wafer on which the ion-implanted layer is formed and the other silicon wafer, heating at a temperature between 300° C. and 900° C., and delaminating from the ion-implanted wafer, and performing a heat treatment of the delaminated wafer at a temperature between 1000° C. and 1300° C., wherein the wafer forming the ion-implanted layer has an interstitial oxygen concentration of 1×10¹⁸/cm³ (old ASTM) or higher, and the method further comprises a step to grow an epitaxial layer on the SOI layer formed in the previous step.

### BACKGROUND OF THE INVENTION

A conventionally known SOI (silicon-on-insulator) wafer is formed by bonding two semiconductor wafers with an oxide film (SiO₂) held between them and thinning a semiconductor wafer which becomes an active side.

For example, Japanese Patent Laid-Open Publication No. 5-211128 discloses a method of producing an SOI wafer by a technology which is called a hydrogen ion delamination method or a smart-cut method.

The production method described in the above publication will be described in detail with reference to FIG. 2.

First, to produce the SOI wafer by the hydrogen ion delamination method, two silicon wafers 50, 51 are prepared (see FIG. 2a), and an oxide film 500 is formed on the surface of the silicon wafer 50 (see FIG. 2b). And, hydrogen ions or rare gas ions are implanted from the surface of the silicon wafer 50, on which the oxide film is formed, under prescribed conditions to form an ion-implanted layer 501 (see FIG. 2c).

Then, a delamination and thin film making steps will be described.

The silicon wafer 50 has 51, which becomes a supporting wafer, superposed on the surface where the oxide film 500 is formed (FIG. 2d). And, when heat treatment is performed at a low temperature (e.g., 400° C. to 600° C.), the superposed silicon wafers 50, 51 are separated with the ion-implanted layer 501 as a delamination plane to form a thin silicon wafer 6 (see FIG. 2e).

Then, the thin silicon wafer 6 is thermally treated at a high temperature to enhance the bonding strength between the supporting side silicon wafer 51 and the surface on which the oxide film 500 is formed, and an SOI wafer 5 having an SOI layer 502 is formed (FIG. 2f).

The SOI wafer formed by the hydrogen ion delamination method has the following advantages. For example, (1) the SOI layer and an embedded oxide film thickness are designed with high flexibility. (2) The SOI layer has remarkable uniformity in thickness. (3) The embedded oxide film has high reliability. (4) Usability of the wafer is high due to multi-utilization of silicon wafer 50. Therefore, the SOI wafer formed by the above method is highly expected to be put into actual use.

Japanese Patent Laid-Open Publication No. 2-37771 discloses another method of producing SOI wafer. This method produces an SOI wafer having gettering sites by forming an oxide film on a first silicon wafer which has the gettering sites formed by a heat treatment, superposing the oxide film-formed surface of the wafer and a second silicon wafer having an oxide film formed, and polishing the first silicon wafer to grow an epitaxial layer.

But, the SOI wafer produced by the hydrogen ion delamination method as described above has lots of crystal defects which are produced in the device formation layer in the present SOI wafer production process or electronic device production process. The presence of crystal defects is a factor to obstruct the practical use of the SOI wafer produced by the hydrogen ion delamination method.

The method of producing the SOI wafer described in Japanese Patent Laid-Open Publication No. 2-37771 had a drawback that the production process is complex because the gettering sites are formed on the first silicon wafer and it is necessary to specially perform the IG (intrinsic gettering) heat treatment.

Therefore, the present invention provides a method of producing a high quality SOI wafer, which has high gettering performance and has reduced crystal defects in the device formation layer, in the production process of the SOI wafer produced by the hydrogen ion delamination method and the production process of the electronic device, and the SOI wafer.

### SUMMARY OF THE INVENTION

One aspect of the present invention described in claim 1 is a method of producing an SOI wafer, comprising the steps of:

forming an ion-implanted layer by forming an oxide film on at least one silicon wafer between two silicon wafers and implanting hydrogen ions or rare gas ions into one silicon wafer,

superposing the surface of the silicon wafer on which the ion-implanted layer is formed and the other silicon wafer, heating at a temperature between 300° C. and 900° C., and delaminating from the ion-implanted wafer, and

performing a heat treatment of the delaminated wafer at a temperature between 1000° C. and 1300° C., wherein: the wafer forming the ion-implanted layer has an interstitial oxygen concentration of 1×10¹⁸/cm³ (old ASTM) or higher, and the method further comprises a step to grow an epitaxial layer on the SOI layer formed in the previous step.

Thus, when a wafer having an interstitial oxygen concentration of 1×10⁸/cm³ (old ASTM) or higher is used to produce the SOI wafer, oxygen precipitates are formed by the heat treatment after the delamination because of the supersaturated oxygen in the wafer, so that the SOI wafer is expected to have an adequate IG effect. In addition, the SOI wafer can be expected to have a gettering effect by a damage layer by the ion implantation. In other words, the SOI layer of the SOI wafer produced by the production method of the present invention has defects such as an oxygen precipitate produced in high density and gettering sites which have a crystal defect density of reaching 1×10² to 1×10⁷/cm² formed, and the SOI wafer having high gettering performance can be produced.

And, when the epitaxial layer (hereinafter called as “the epi-layer”) is formed on the SOI layer, the SOI wafer of high quality can be produced with crystal defects reduced in the SOI wafer surface layer which becomes the device formation layer.

According to the production method of the present invention, the delamination process performed by a low-temperature heat treatment (between 300° C. and 900° C.) also serves as an oxygen precipitate nucleus formation step, and the subsequent bonding strength enhancing process serves as an oxygen precipitate formation step at a high temperature (between 1000° C. and 1300° C.). Therefore, it is not necessary to perform the IG heat treatment to specially form an oxygen precipitate in order to form the gettering sites, the number of production steps can be reduced, and the SOI wafer of high quality can be produced efficiently.

Another aspect described in claim 2 of the present invention is a method of producing an SOI wafer, comprising the steps of:

forming an ion-implanted layer by forming an oxide film on at least one silicon wafer between two silicon wafers and implanting hydrogen ions or rare gas ions into one silicon wafer, and

superposing the surface of the silicon wafer on which the ion-implanted layer is formed and the other silicon wafer, heating at a temperature between 300° C. and 900° C., and delaminating from the ion-implanted wafer, wherein:

the wafer forming the ion-implanted layer has an interstitial oxygen concentration of 1×10¹⁸/cm³ (old ASTM) or higher, and the method further comprises a step to grow at a temperature between 1000° C. and 1300° C. an epi-layer on the wafer formed in the previous step.

Thus, when the epi-layer growing step is performed at a high temperature between 1000° C. and 1300° C., the gettering sites can be formed in the SOI when the epi-layer is grown, the production steps can be simplified, and the SOI wafer of high quality free from crystal defects in the SOI wafer surface layer can be obtained.

Another aspect described in claim 3 of the present invention is an SOI wafer having an epitaxial layer, comprising an intrinsic gettering (IG) layer having a crystal defect density of 1×10² to 1×10⁷/cm² in an SOI layer.

The SOI wafer of the present invention has an interstitial oxygen concentration of 1×10¹⁸/cm³ (old ASTM) or higher, the gettering sites having a crystal defect density of 1×10² to 1×10⁷/cm² can be formed in the SOI layer mainly by the supersaturated oxygen, and a high intrinsic gettering effect is produced. And, the SOI wafer surface layer is formed with the epi-layer, so that a high quality product with a crystal defect reduced in the device formation layer is obtained.

### BRIEF DESCRIPTION OF THE DRAWINGS

FIG. 1 is a flow chart showing respective steps of producing an SOI wafer according to an embodiment of the present invention; and

FIG. 2 is a flow chart showing respective steps of producing an SOI wafer according to a prior art.

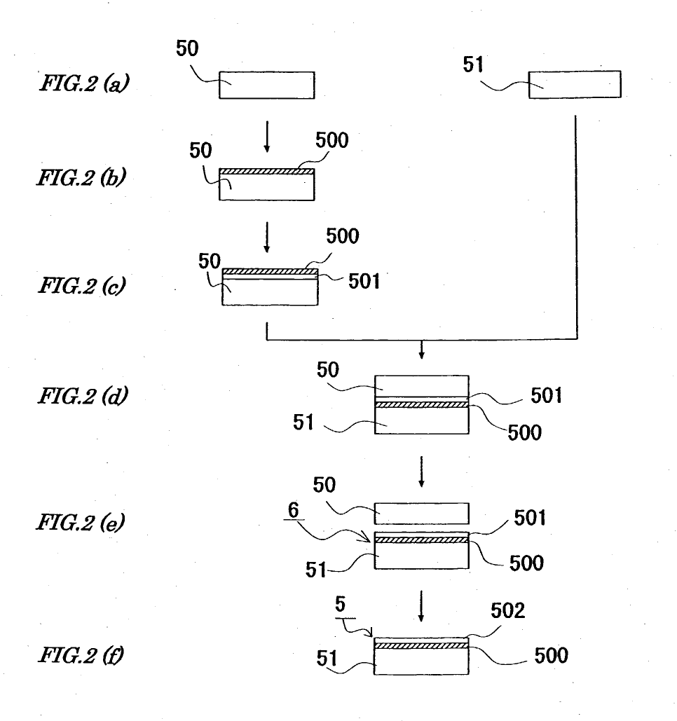

### DESCRIPTION OF THE PREFERRED EMBODIMENTS

A specific embodiment of the present invention will be described in detail with reference to the drawing.

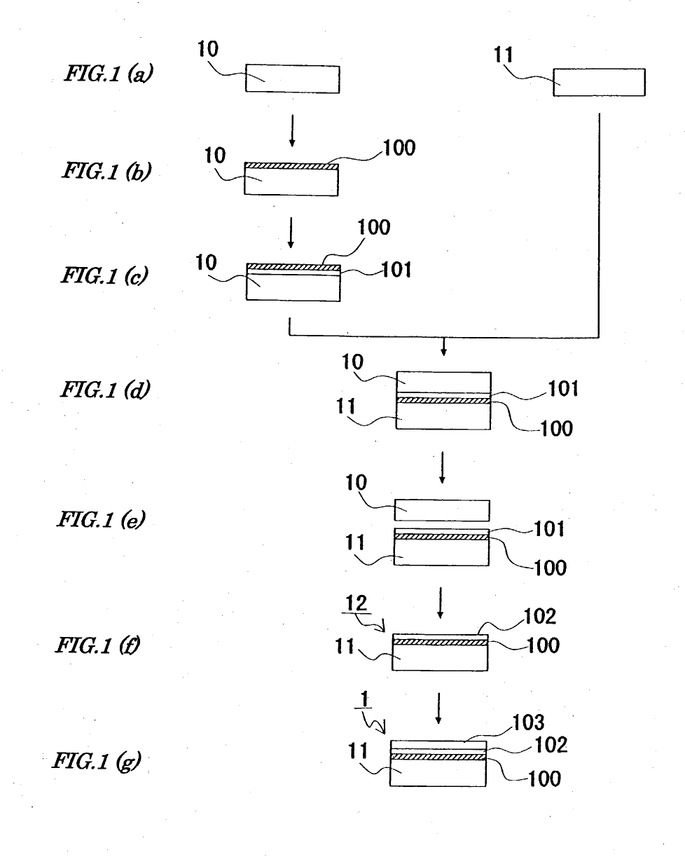

FIG. 1 is a flow chart showing a production process of the present invention.

First, two silicon wafers 10, 11 are prepared (see FIG. 1a). In this embodiment, the wafer 10 is a wafer which forms an ion-implanted layer, and the wafer 11 is a supporting-side wafer. The wafer 10 which forms the ion-implanted layer is a silicon wafer having a high interstitial oxygen concentration of 1×10¹⁸/cm³ (old ASTM; the same is applied below) or higher.

At least one of the two wafers 10, 11, which is the wafer 10 in this embodiment, is thermally treated to form a thermally-oxidized film 100 of 0.1 μm on the surface (see FIG. 1b).

Then, hydrogen ions or rare gas ions are implanted into the wafer 10 to form an ion-implanted layer 101 (FIG. 1c). In this embodiment, the hydrogen ions are implanted into the wafer 10 through the oxide film 100 under conditions of an acceleration voltage of 80 KeV and a dose amount of 5×10¹⁶/cm².

Then, the surface of the wafer 10 on which the thermally-oxidized film 100 is formed is superposed on the supporting side wafer 11 (FIG. 1d).

Heat treatment was performed at 500° C. for one hour in an N2 atmosphere to partly peel the wafer 10 among the superposed silicon wafers from the position of the ion-implanted layer 101 (FIG. 1e).

Besides, heat treatment was performed at 1100° C. for two hours in an N2 atmosphere to enhance a bonding strength between the oxide film 100 of the remained wafer 10 and the supporting side wafer 11 so as to form an SOI wafer 12 having an SOI layer 102 (FIG. 1f). Here, by the heat treatment at a high temperature, an oxygen precipitate is formed on the SOI wafer 12 from supersaturated oxygen in the wafer to form the gettering sites in the SOI layer 102.

Then, a heat treatment was performed at 1100° C. in an SiHCl₃ atmosphere to obtain an SOI wafer 1 which has an epi-layer 103 with a thickness of 5 μm formed on the SOI layer (FIG. 1g).

The obtained SOI wafer 1 was evaluated for a defect density by a selective etching method.

As a result of the evaluation, it was found that a defect density in the epi-layer 103 had a good value of 1×10²/cm² or below and a defect density in the SOI layer 102 below the epi-layer 103 was 1×10² to 1×10⁵/cm², indicating the values adequate to obtain a gettering effect. And, the defects in the SOI layer 102 were observed through a transmission electron microscope to confirm that such defects were oxygen precipitates.

As described above, when a wafer having the interstitial oxygen concentration of 1×10¹⁸/cm³ (old ASTM) or higher is used as the wafer 10 to form the ion-implanted layer in the method of producing the SOI wafer 1 by the hydrogen ion delamination method, adequate gettering sites are formed by the heat treatment after the delamination because of the supersaturated oxygen. And, the gettering effect of a damage layer by the ion implantation can also be expected.

Accordingly, the SOI layer 102 has defects such as oxygen precipitates or the like in high density and the gettering sites with a crystal defect density of up to 1×10² to 1×10⁷/cm² is formed. Thus, the SOI wafer having high gettering performance can be produced.

The SOI wafer 1 has the epi-layer 103 on the surface layer, so that crystal defects are reduced in the surface layer of the SOI wafer 1 which becomes a device formation layer, and the SOI wafer 1 of high quality can be produced.

According to the production method of this embodiment, the delamination step (FIG. 1e) performed at a low-temperature heat treatment (between 300° C. and 900° C.) also serves as an oxygen precipitation nucleus formation step, and the subsequent bonding strength enhancing step (FIG. 1f) at a high temperature (between 1000° C. and 1300° C.) also serves as an oxygen precipitate formation step. Therefore, it is not necessary to perform an IG heat treatment to form only the oxygen precipitates in order to form gettering sites. Thus, the number of production steps can be reduced, and the SOI wafer 1 of high quality can be produced efficiently.

Then, a second specific embodiment of the SOI wafer production process will be described. The method of this embodiment is performed in the same way as the flow of the production process shown in FIG. 1 up to the delamination step (FIGS. 1a to 1e).

In the method of this embodiment, the bonding strength enhancing step by the high-temperature heat treatment shown in FIG. 1f is omitted, the delamination step shown in FIG. 1(e) is performed, a heat treatment is performed at 1100° C. in an SiHCl₃ atmosphere as shown in FIG. 1(g) to perform the steps of forming the SOI layer 102 and the epi-layer 103.

The SOI wafer produced by the method of this embodiment was found that a defect density in the epi-layer 103 had a good value of 1×10²/cm² or below, and a defect density in the SOI layer 102 below the epi-layer 103 was 1×10² to 1×10⁵/cm², indicating an adequate value to obtain a gettering effect.

Thus, when the step of growing the epi-layer 103 is performed at a high temperature between 1000° C. and 1300° C., gettering sites can be formed in the SOI layer 102 at the same time when the epi-layer 103 is grown, the production process is simplified, and the SOI wafer of high quality which has crystal defects reduced on the SOI wafer surface layer which becomes the device formation layer can be produced.

What is claimed is:

1. A method of producing an SOI wafer, comprising the steps of:
forming an ion-implanted layer by forming an oxide film on at least one silicon wafer between two silicon wafers and implanting hydrogen ions or rare gas ions into one silicon wafer,
superposing the surface of the silicon wafer on which the ion-implanted layer is formed and the other silicon wafer, heating at a temperature between 300° C. and 900° C., and delaminating from the ion-implanted wafer, and
performing a heat treatment of the delaminated wafer at a temperature between 1000° C. and 1300° C., wherein:
the wafer forming the ion-implanted layer has an interstitial oxygen concentration of 1×10⁸/cm³ (old ASTM) or higher, and the method further comprises a step to grow an epitaxial layer on the SOI layer formed in the previous step.

2. A method of producing an SOI wafer according to claim 1, wherein an intrinsic getting (IG) layer is formed, said intrinsic getting (IG) layer having a crystal defect density of 1×10² to 1×10⁷/cm² in the SOI layer, and the crystal defect density in the epitaxial layer is less than 1×10²/cm².

3. A method of producing an SOI wafer, comprising the step of:
forming an ion-implanted layer by forming an oxide film on at least one silicon wafer between two silicon wafers and implanting hydrogen ions or rare gas ions into one silicon wafer, and
superposing the surface of the silicon wafer on which the ion-implanted layer is formed and the other silicon wafer, heating at a temperature between 300° C. and 900° C., and delaminating from the ion-implanted wafer, wherein:
the wafer forming the ion-implanted layer has an interstitial oxygen concentration of 1×10¹/cm³ (old ASTM) or higher, and the method further comprises a step to grow at a temperature between 1000° C. and 1300° C. an epitaxial layer on the wafer formed in the previous step.

4. A method of producing an SOI wafer according to claim 3, wherein an intrinsic gettering (IG) layer is formed, said intrinsic getting (IG) layer having a crystal defect density of 1×10² to 1×10⁷/cm² in the SOI layer, and the crystal defect density in the epitaxial layer is less than 1×10²/cm².
